(19) United States
(12) Patent Application Publication
(10) Pub. No.: US 2007/0199678 A1
(43) Pub. Date: Aug. 30, 2007

(54) Surface Coating Film Structure on Heat Dissipation Metal and Manufacturing Method Thereof

(76) Inventors: Ming-Hang Hwang, Taipei City (TW); Yu-Chiang Cheng, Taipei City (TW); Chao-Yi Chen, Taipei City (TW); Hsin-Lung Kuo, Taipei City (TW); Bin-Wei Lee, Taipei City (TW); Wei-Chung Hsiao, Taipei City (TW)

Correspondence Address: LAW OFFICES OF LAI AND ASSOCIATES, P.C., 5800 RANCHESTER STE 200, HOUSTON, TX, 77036, US

(21) Appl. No.: 11/307,841

(22) Filed: Feb. 24, 2006

(51) Int. Cl. H05K 7/20

(52) U.S. Cl. 165/80.3; 165/133; 361/704

(57) ABSTRACT

This invention discloses a manufacturing method and the structure for a surface coating film on a heat dissipation metal. The surface coating film structure on the heat dissipation metal includes a heat dissipation metal and a thin film. The surface coating film structure on the heat dissipation metal is often used in dissipation the waste heat from the electronic apparatuses. The thin film is composed of a bracket structure of carbon element which has high thermal conductivity, so as to improve the efficiency of heat dissipation of the heat dissipation metal. The corresponding manufacturing method for the thin film can be made with chemical vapor deposition, physical vapor deposition or the other material preparation methods.

### FIELD OF THE INVENTION

The present invention relates to a surface coating film structure on a heat dissipation metal and corresponding manufacturing method and, more particularly, to the manufacturing method for making a thin film having a bracket structure of carbon element.

### BACKGROUND OF THE INVENTION

As the technology innovated, various electronic apparatuses are developed, as computer system, mobile phone, MP3, digital camera, media player, translator, personal digital assistant (PDA), scanner, remote controller, global positioning system (PDA), etc. The development of electronic apparatuses is toward small volumes and high densities. The efficiency requirements for the chips within the electronic apparatuses also increase that generates much waste heat. The performances of the electronic apparatuses will be decreased if the waste heat is unable to eliminate appropriately.

Therefore, various heat dissipation appliances are provided to improve the efficiency of heat dissipation. In the prior art, the material applying in the heat dissipation appliances usually includes copper or aluminum alloy to be the tendency of current heat dissipation technique. The heat dissipation appliances are applied to various electronic apparatus chips like North Bridge, South Bridge, or memories.

Referring to FIG. 1, a schematic diagram illustrates a heat dissipation appliance applying for a North Bridge. The heat dissipation appliance for the North Bridge comprises a square plate 11 and a plurality of heat sink fins 12. The square plate 11 has an upper surface 111 and a lower surface 112. A connected hemline 121 is composed of a hemline of each fin of the plurality of heat sink fins 12. The connected hemline 121 is connected to the upper surface 111 of the square plate 11. Each fin is preset to arrange side by side that is vertically connected to the upper surface 111 of the square plate 11 to enable the plurality of heat sink fins 12 to erect on the square plate 11, so as to form the heat dissipation appliance for the North Bridge. The lower surface 112 of the square plate 11 is pasted on the chip. The square plate 11 and the plurality of heat sink fins 12 can be made by copper or aluminum. The heat dissipation is that the lower surface 112 of the square plate 11 is pasted on the North Bridge to conduct waste heat first. The waste heat is then conducted to the plurality of heat sink fins 12 which is connected to the upper surface 111. Lastly, the waste heat existed in the plurality of heat sink fins 12 is discharged through air convection from the outside.

In addition, referring to FIG. 2, a schematic diagram illustrates a heat dissipation appliance applying for a memory. The heat dissipation appliance for the memory comprises a pair of metal plates with rectangle 21 and a [symbol] -type clamp 22. The [symbol] -type clamp 22 has a rectangle top surface 221. Two edges 222 extend downward to form a [symbol] -type side edge 223 respectively. A space 212 is formed by the pair of metal plates with rectangle 21 to set the memory. The pair of metal plates with rectangle 21 and the [symbol] -type clamp 22 are made by copper or aluminum. The heat dissipation is that the memory is set in the space 212 formed by the pair of metal plates with rectangle 21 and the pair of metal plates with rectangle 21 is closely pasted to the memory to conduct the waste heat. Lastly, the waste heat existed in the pair of metal plates with rectangle 21 is discharged through air convection from the outside.

However, the structures of above heat dissipation appliances are restricted by the conformation of the heat sink fin. The head dissipation appliance further needs to be contracted to face the space restriction except satisfy the heat dissipation requirement. Although the heat pipe is developed to satisfy the efficiency of heat dissipation, the contraction is still to be broken through.

Besides, diamonds are well known and have characteristics with the highest hardness, the fastest heat conduction, and the widest refraction range in current materials. Diamonds, therefore, are always one of more important materials in engineering due to the excellent characteristics. The thermal conductivity of diamonds at the normal atmospheric temperature is five times more than copper. Moreover, the thermal expansion factor of diamonds at high temperature is very small that shows the excellent efficiency for heat dissipating. The feature may help people to differentiate the adulteration of diamonds. In the prior art, many technologies and manufacture procedures have been developed to make diamonds. The direct decomposition for hydrocarbons is the most familiar method like Microwave Plasma Enhance Chemical Vapor Deposition (MPCVD) and Hot Filament CVD (HFCVD). By the aforesaid methods, polycrystalline diamond films can be deposited. The characteristic of the polycrystalline diamond films is same as the single crystal diamonds.

Accordingly, a heat dissipation structure and a manufacturing method are provided to satisfy both the heat dissipation demand and the contraction.

### SUMMARY OF THE INVENTION

The inventor of the present invention based on years of experience on related research and development of the heat dissipation device to invent a heat dissipation structure and a manufacturing method to overcome the foregoing shortcomings.

The object of the present invention is to provide a surface coating film structure on a heat dissipation metal and corresponding manufacturing method applying for an electronic apparatus, such as a computer system or a consumer electronic product, to conduct heat generated by the electronic apparatus. The surface coating film structure on the heat dissipation metal comprises at least a heat dissipation metal and a thin film having a bracket structure of carbon element. The thin film is coated on a surface of the heat dissipation metal. The heat dissipation metal can be copper, aluminum or a metal material with high thermal conductivity. The thin film is diamonds and can be made by chemical vapor deposition (CVD), physical vapor deposition (PVD) or other preparation methods.

Other features and advantages of the present invention and variations thereof will become apparent from the following description, drawings, and claims.

### BRIEF DESCRIPTION OF THE DRAWINGS

FIG. 1 is schematic diagram illustrating a heat dissipation appliance applying for a North Bridge;

FIG. 2 is a schematic diagram illustrating a heat dissipation appliance applying for a memory;

FIG. 3 is a schematic diagram illustrating microwave plasma enhanced chemical vapor deposition making a surface coating film structure according to a preferred embodiment of the present invention;

FIG. 4 is a schematic diagram illustrating ion beam sputtering making a surface coating film structure according to another embodiment of the present invention; and

FIG. 5 is a perspective drawing illustrating a surface coating film structure on a heat dissipation metal according to an embodiment of the present invention;

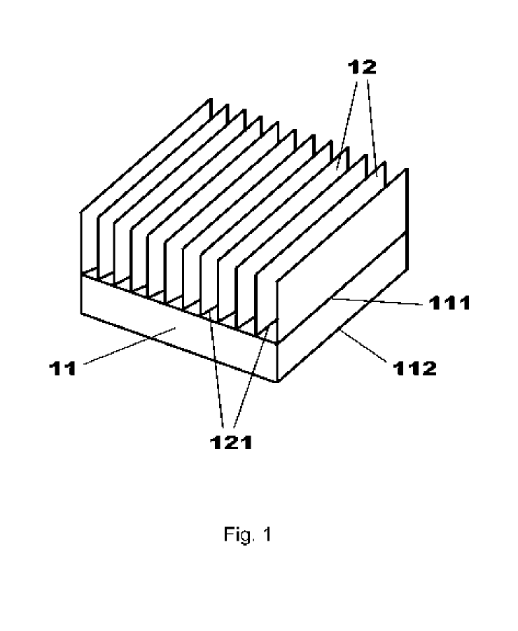

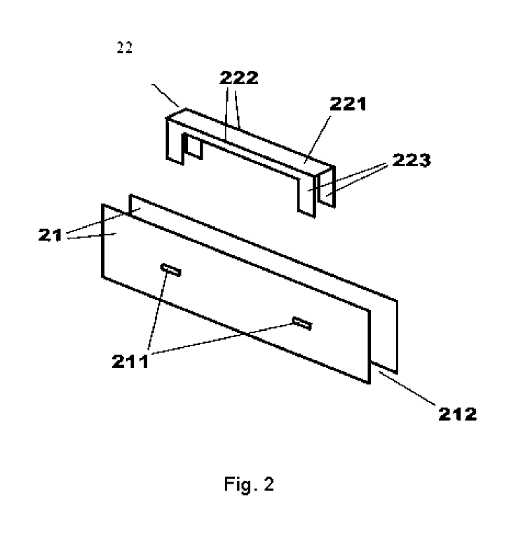

### DETAILED DESCRIPTION OF THE PREFERRED EMBODIMENTS

In the manufacturing method of making a surface coating film structure on a heat dissipation metal, the thin film having the bracket structure of carbon element can be made by chemical vapor deposition (CVD) or physical vapor deposition (PVD), so as to coat on a surface of a metal.

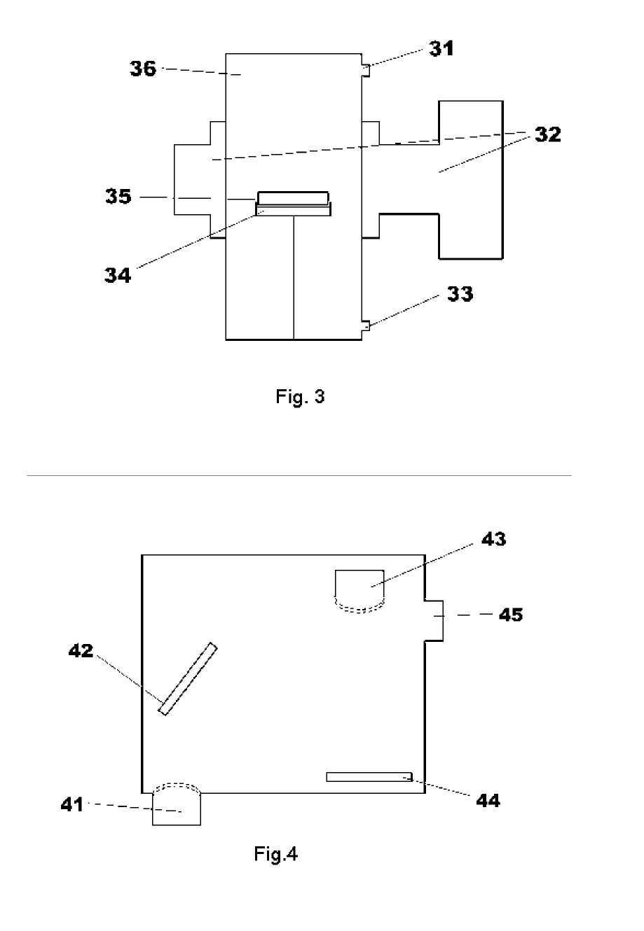

Referring to FIG. 3, a schematic diagram illustrates microwave plasma enhanced chemical vapor deposition making a surface coating film structure according to a preferred embodiment of the present invention. In the embodiment, the reaction procedure is that a mixed gas for desired reaction is delivered to a gas reaction room 36 from a gas entrance 31. At the same time, a microwave is generated by a microwave generation system 32 to activate the mixed gas in order to provide reactive ions for reacting. A surface of a metal material 35 on a carrier 34 is absorbed to form diamond films. The metal material 35 is a planar heat dissipation metal which can be copper, aluminum or a metal material with high thermal conductivity or other material combinations. Remaining gas is discharged via a waste gas exit 33. By the way mentioned above, the planer heat dissipation metal coated by the surface coating film structure can be acquired.

Referring to FIG. 4, a schematic diagram illustrates ion beam sputtering making a surface coating film structure according to another embodiment of the present invention. In the embodiment, the manufacturing procedure is that a target 42 is molded by diamond materials first of all. The placement angle of the target 42 and the shooting direction of ion beam of a first ion gun 41 are approximately forty five degrees. The diamond particles fired by the first ion gun 41 fly to the front of a second ion gun 43. The diamond particles is then sputtered to the surface of a metal material 44 to form uniform diamond films by providing enough kinetic energy from the first ion gun 41. The metal material 44 is a planar heat dissipation metal which can be copper or aluminum or other metals with high heat conductivity or other material combinations. The remaining diamond particles are discharged by a waste gas exit 45. By the way mentioned above, the planar heat dissipation metal coated by the surface coating film structure can be acquired.

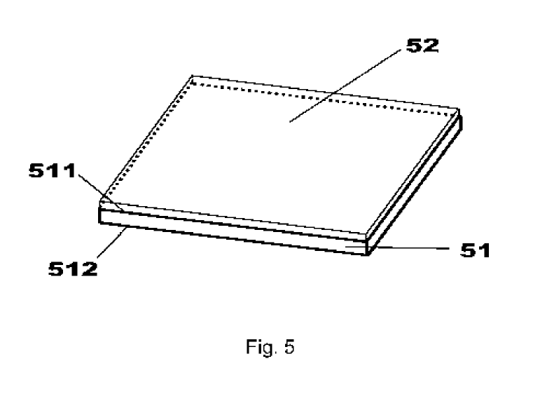

The surface coating film structure on the heat dissipation metal made by above manufacturing methods is shown in FIG. 5. A heat dissipation metal 51 is a flat surface which has an upper surface 511 and a lower surface 512, and a thin film 52 is coated on the upper surface 511 of the heat dissipation metal 51. The thin film 52 is composed of a bracket structure of carbon element which can be diamonds. The heat dissipation metal 51 can be copper or aluminum or a metal material with high thermal conductivity. The lower surface 512 of the heat dissipation metal 51 is pasted on the electronic apparatus. Therefore, the heat dissipation is that the heat generated by the electronic apparatus is conducted to the lower surface 512 of the heat dissipation metal 51 and is then diffused to the upper surface 511 of the heat dissipation metal 51. Lastly, the heat is conducted to the diamond film 52 which is coated on the upper surface 511, the planar heat dissipation appliance can be formed by way of excellent thermal conduction of the diamond film. The spaces occupied by the traditional heat dissipation appliance can be saved to contract the volume of the electronic apparatus and improve the efficiency of heat dissipation.

Although the features and advantages of the embodiments according to the preferred invention are disclosed, it is not limited to the embodiments described above, but encompasses any and all modifications and changes within the spirit and scope of the following claims.

What is claimed is:

1. A surface coating film structure on a heat dissipation metal, applied for an electronic apparatus, comprising:
at least a heat dissipation metal having at least a heat dissipation metal surface; and
a thin film being composed of a bracket structure of carbon element and, formed upon said heat dissipation metal surface.

2. The surface coating film structure on a heat dissipation metal of claim 1, wherein said electronic apparatus is a computer system.

3. The surface coating film structure on a heat dissipation metal of claim 1, wherein said electronic apparatus is a consumer electronic product.

4. The surface coating film structure on a heat dissipation metal of claim 1, wherein said at least a heat dissipation metal is a flat surface.

5. The surface coating film structure on a heat dissipation metal of claim 1, wherein said heat dissipation metal is copper.

6. The surface coating film structure on a heat dissipation metal of claim 1, wherein said heat dissipation metal is aluminum.

7. The surface coating film structure on a heat dissipation metal of claim 1, wherein said heat dissipation metal is a metal material with high thermal conductivity.

8. The surface coating film structure on a heat dissipation metal of claim 1, wherein said bracket structure of carbon element is diamonds.

9. The surface coating film structure on a heat dissipation metal of claim 1, wherein said surface plating film structure is made by chemical vapor deposition (CVD).

10. The surface coating film structure on a heat dissipation metal of claim 1, wherein said surface plating film structure is made by physical vapor deposition (PVD).

11. A manufacturing method for making a surface coating film structure on a heat dissipation metal, comprising:
providing a heat dissipation metal; and
employing a manufacturing process to produce a thin film having a bracket structure of carbon element on said heat dissipation metal.

12. The manufacturing method of claim 11, wherein said heat dissipation metal is copper.

13. The manufacturing method of claim 11, wherein said heat dissipation metal is aluminum.

14. The manufacturing method of claim 11, wherein said heat dissipation metal is a metal material with high thermal conductivity.

15. The manufacturing method of claim 11, wherein said bracket structure of carbon element is diamonds.

16. The manufacturing method of claim 11, wherein said thin film is made by chemical vapor deposition (CVD).

17. The manufacturing method of claim 11, wherein said thin film is made by PVD.
